(19) United States
(12) Patent Application Publication
(10) Pub. No.: US 2008/0205179 A1
(43) Pub. Date: Aug. 28, 2008

(54) INTEGRATED CIRCUIT HAVING A MEMORY ARRAY

(75) Inventors: Michael Markert, Augsburg (DE); Michael Angerbauer, Freutsmoos (DE); Corvin Liaw, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/680,305

(22) Filed: Feb. 28, 2007

(51) Int. Cl. G11C 7/12

(52) U.S. Cl. 365/207

(57) ABSTRACT

An integrated circuit having a memory array and a method for reducing sneak current in a memory array is disclosed.

One embodiment provides a memory array including a plurality of storage devices arranged as a plurality of rows and a plurality of columns. A first voltage is applied to a particular word line to select a column of storage devices. A second voltage is applied to a particular bit line of the plurality of bit lines to select a row of storage devices, and the second voltage is applied to each of further lines except for a further line being connected to the storage devices of the selected column.

### BACKGROUND

The invention relates to an integrated circuit having a memory array, in one embodiment to a memory array including resistive memory elements. Further, the invention relates to a method for reducing sneak current in an integrated circuit having a memory array.

In conventional semiconductor memory devices one differentiates between functional memory devices (e.g., PLAs, PALs, etc.) and table memory devices, e.g., ROM devices (ROM=Read Only Memory)—in particular PROMs, EPROMs, EEPROMs, flash memories, etc.—, and RAM devices (RAM=Random Access Memory or read-write memory), e.g., DRAMs (Dynamic Random Access Memory or dynamic read-write memory) and SRAMs (Static Random Access Memory or static read-write memory).

A RAM device is a memory for storing data under a predetermined address and for reading out the data under this address later. Since it is intended to accommodate as many memory cells as possible in a RAM device, one has been trying to realize same as simple as possible and to scale it as small as possible.

In the case of SRAMs, the individual memory cells consist e.g., of few, for instance 6, transistors, and in the case of DRAMs in general only of one single, correspondingly controlled capacitive element, e.g., a trench capacitor, with the capacitance of which one bit each can be stored as charge.

In the case of such dynamic semiconductor memories, the information or charge, respectively, in the memory cell remains stored for a relatively short time only. By the “diffusion” of the charge carriers, the memory contents may leave the cell and may flow into the cell environment. Therefore, a “refresh” must be performed regularly, e.g., approximately every 64 ms. In contrast to that, no “refresh” has to be performed in the case of SRAMs since the data stored in the memory cell remains stored as long as an appropriate supply voltage is fed to the SRAM.

In the case of non-volatile memory devices (NVMs), e.g., EPROMs, EEPROMs, and flash memories, the stored data remains, however, stored even when the supply voltage is switched off.

Furthermore, resistive memory devices, e.g., Magnetic Random Access Memories (MRAMs), Phase Change Random Access Memories (“PCRAMs”), Conductive Bridging Random Access Memories (“CBRAMs”), etc., have recently become known. The general advantage of the resistive memory devices vis-à-vis conventional semiconductor memories may e.g., be seen in the permanent storage of the information, combined e.g., with a relatively small cell size, and/or relatively small access times. After the switching off and the new switching on of the device in which the memory devices are used, the information stored is available instantly. Further, energy-consuming “refresh” cycles that are required with conventional DRAM semiconductor chips may be eliminated.

The functioning of a resistive memory device provides to store, for example, one bit of information each, i.e. a logic “0” or a logic “1”, in a memory element having, for example, two distinct conductive states (wherein e.g., the more conductive state corresponds to a stored logic “1”, and the less conductive state to a stored logic “0”, or vice versa).

In the case of MRAMs (Magnetic Random Access Memories), the functioning of a MRAM provides to store one bit of information each in a memory element that consists substantially of two magnetized layers that are adapted to either be magnetized parallel or anti-parallel to each other. In a MRAM memory device, a memory array consisting of a plurality of storage devices (including the memory elements) and of a matrix of row supply lines (so-called bit lines) and column supply lines (so-called word lines and PL lines), respectively, is constructed. These supply lines consist of electrically conductive material, wherein the actual MRAM storage device is positioned at the crosspoints of the supply lines. To achieve a change in the magnetization of a memory element, a magnetic field, the strength of which has to exceed a certain threshold value, is selectively generated by the column and row supply lines in the direct vicinity of a freely addressable crosspoint.

The column and row supply lines do not only serve to generate magnetic fields for write operations, but they also conduct the read currents for reading out the binary information stored in the memory elements. The magnetic memory state of a memory element is determined by the measurement of a particular physical property, namely the electric resistance, at and through the memory element itself.

In the case of PCRAMs (Phase Change Random Access Memories), an “active” or “switching active” material—which is, for instance, positioned between two appropriate electrodes—is placed, by appropriate switching processes, in, e.g., two, distinct conductive states. As a “switching active” material, for instance, an appropriate chalcogenide or chalcogenide compound material may be used (e.g., a Ge—Sb—Te (“GST”) or an Ag—In—Sb—Te compound material, etc.). The chalcogenide compound material is adapted to be placed in an amorphous, i.e. a relatively weakly conductive, or a crystalline, i.e. a relatively strongly conductive state by appropriate switching processes.

In order to achieve, with a corresponding PCRAM memory element, a change from the above-mentioned amorphous, i.e. a relatively weakly conductive state of the switching active material, to the above-mentioned crystalline, i.e. a relatively strongly conductive state of the switching active material, an appropriate relatively high heating current pulse has to be applied to the electrodes, the heating current pulse resulting in that the switching active material is heated beyond the crystallization temperature and crystallizes (“writing process”).

Vice versa, a change of state of the switching active material from the crystalline, i.e. a relatively strongly conductive state, to the amorphous, i.e. a relatively weakly conductive state, may, for instance, be achieved in that—again by an appropriate (relatively high) heating current pulse—the switching active material is heated beyond the melting temperature and is subsequently “quenched” to an amorphous state by quick cooling (“erasing process”).

Typically, the above erase or write heating current pulses are provided via respective bit lines and PL lines, and respective FET or bipolar access transistors associated with the respective memory elements, and controlled via respective word lines.

In the case of CBRAMs (Conductive Bridging Random Access Memories), an “active” or “switching active” material—which is, for instance, positioned between two appropriate electrodes—is placed, by appropriate switching processes, in, e.g., two, distinct conductive states. The storing of data is performed by use of a switching mechanism based on the statistical bridging of multiple metal rich precipitates in the “switching active” material. Upon application of a write pulse (positive pulse) to two respective electrodes in contact with the “switching active” material, the precipitates grow in density until they eventually touch each other, forming a conductive bridge through the “switching active” material, which results in a high-conductive state of the respective CBRAM memory element. By applying a negative pulse to the respective electrodes, this process can be reversed, hence switching the CBRAM memory element back in its low-conductive state.

Correspondingly similar as is the case for the above PCRAMs, for CBRAM memory elements, an appropriate chalcogenide or chalcogenid compound (for instance GeSe, GeS, AgSe, CuS, etc.) may be used as “switching active” material.

As described above, in resistive memory devices, it is desired that the range between high ohmic state and low ohmic state of a memory element is as large as possible.

This is especially important for a multi level operation of a resistive memory element, also referred to as multi level cell. In a resistive multi level cell, there exist multiple distinct levels of the ohmic conductivity of the memory element (not only “high” and “low”) enabling storage of multiple bits per memory cell. This, however, leads to smaller intervals between the different levels of the ohmic conductivity of the memory element requiring an even larger range of the ohmic conductivity of the memory element.

Hereby, the lower limit of the resistance of the memory element may be given by the voltage on the element that is needed to switch the element to the high ohmic state. The voltage on the element is the operating voltage minus the voltage drop on the bit line and minus the voltage drop on the select device. To achieve a higher voltage on the memory element, the voltage drop on the select device has to be minimized. Thus, the lowest useful resistance of the memory element depends on the “on-resistance” of the select device. Decreasing the “on-resistance” on the select device also increases the “off-resistance” leading to higher sneak currents.

There are a lot of storage devices including the select devices and memory elements on an active bit line, the sneak current on the bit line is the sum of all single sneak currents on the active bit line. Each single current depends on the stored information in the respective memory element. A high ohmic element leads to nearly no sneak current, a low ohmic element leads to a higher sneak current. Thus, the overall sneak current varies depending on the number of low ohmic memory elements on the active bit line. This varying sneak current leads to problems in sensing the correct value of a selected memory element.

Therefore, there e.g., exists a need for a memory array which provides accurate currents on an active bit line, for example, when sensing a stored value (the ohmic state) of a resistive memory element, in particular of a resistive multi level cell or resistive multi level element, respectively.

For these or other reasons, there is a need for the present invention.

### SUMMARY

One embodiment provides an integrated circuit having a memory array. The integrated circuit having a plurality of storage devices arranged as a plurality of rows and a plurality of columns. The memory array is configured to reduce sneak currents including receiving a first voltage applied to a particular word line to select a column of storage devices, and a second voltage applied to a particular bit line of the plurality of bit lines to select a row of storage devices, and wherein the second voltage is applied to each of further lines except for a further line being connected to the storage devices of the selected column.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates an exemplary schematic diagram of a section of a memory array including resistive memory elements according to an embodiment of the invention.

FIG. 2 illustrates a schematic simplified flowchart illustrating a method for reducing sneak current in a memory array in accordance with a further embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The invention relates to an integrated circuit having a memory array, in one embodiment to a memory array including resistive memory elements. Further, the invention relates to a method for reducing sneak current in an integrated circuit having a memory array.

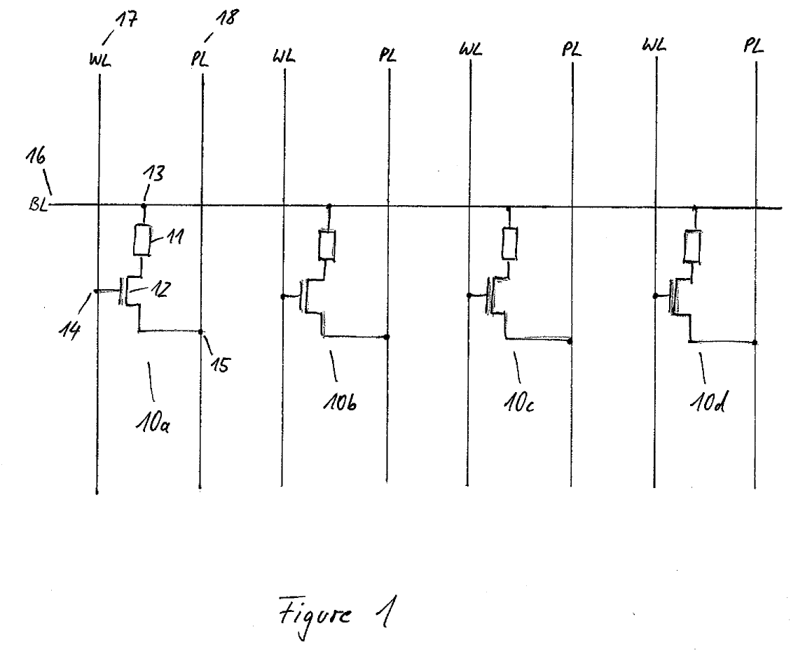

FIG. 1 illustrates an exemplary schematic diagram of a section of an integrated circuit having a memory array including resistive memory elements according to an embodiment of the invention.

In the memory array, a plurality of storage devices are arranged in rows and columns similar to a matrix. A storage device 10a, often also referred to as memory cell, includes a select device 12, e.g., a transistor, in particular a field effect transistor (FET), (but other suitable select devices may also be used), a resistive memory element 11, a first connection or pin 13, a second connection or pin 14, and a third connection or pin 15.

The storage devices (10a, 10b, 10c, 10d) of one row are each connected with their respective first connection to an associated bit line 16 and the storage devices of one column are each connected with their respective second connection to an associated word line 17 and are also each connected with their respective third connection to an associated PL line 18.

In one embodiment illustrated in FIG. 1, the storage device 10a is arranged as follows: the memory element 11 is connected to the first connection 13 and also connected to the source of the transistor 12. Further, the transistor 12 is connected with its gate to the second connection 14 and with its drain to the third connection 15. However, other designs of the storage device 10a are also possible, i.e. the components of the storage device may also be connected in a different way: For instance, the memory element 11 may be connected to the third connection 15 and to the drain of the transistor 12. Further, the transistor 12 may be connected with its gate to the second connection 14 and with its source to first connection 13, etc.

When a particular storage device 10a is to be read out, the particular storage device 10a is addressed by applying a read voltage to the bit line 16 (in the following referred to as active bit line) to which the storage device 10a is connected with its first connection 13. As only the particular storage device 10a should be read out, the particular storage device 10a is selected by applying, via the associated word line 17, an appropriate voltage to the select device 12 to cause the select device 12 to be electrically conductive. In contrast, the select devices of all other storage devices connected to the active bit line 16 remain in a non-conductive state.

When the select device 12 is in a conductive state, a current will flow from the active bit line 16, via the first connection 13, through the memory element 11 and the select device 12, via the third connection 15 to the PL line 18. By sensing this current which value is dependent on the ohmic state of the memory element 11 (high electric conductivity vs. low electric conductivity or, in the case of a multi level memory cell, multiple distinct levels of electric conductivity), the value stored in the selected storage device 10a and memory element 11, respectively, is read out: for example, “1” corresponds to a high electric conductivity and “0” corresponds to a low electric conductivity, or vice versa, or, in the case of a multi level cell, the stored value includes multiple bits corresponding to multiple distinct levels of electric conductivity.

If the select devices of the memory array have a low “on-resistance” which, as explained before, may be desirable for resistive memory elements, in particular for multi level resistive memory elements, to have a large range between high ohmic state and low ohmic state also the “off-resistance” of the select devices will be low.

Therefore, in conventional memory arrays including resistive memory elements, a small current, in the following referred to as sneak current, may also flow on the active bit line through non-selected storage devices (whose select devices are in an “off-state”) which are connected with the active bit line. The respective sneak currents are dependent on the ohmic state of the respective memory elements of the non-selected storage devices connected with the active bit line. Therefore, as there are multiple storage devices arranged in one row of a memory array and therefore multiple storage devices connected to one bit line (i.e. also to the active bit line) the multiple differing sneak currents sum up to a total cumulative sneak current on the active bit line, which is dependent on the respective ohmic states of the respective memory elements of the non-selected storage devices connected with the active bit line. This may involve problems in sensing the correct value of the selected storage device in conventional memory arrays including resistive memory elements, in particular multi level resistive memory elements.

In one embodiment, the read voltage, i.e. a voltage equal to the second voltage applied to the active bit line, is applied to the PL lines which are connected to the storage devices 10b, 10c, 10d which are connected to the active bit line, but which are not addressed and selected, respectively, i.e. which are not connected to the selected word line 17 to which a voltage is applied. Thus, a difference in potential is present between the first connection 13 and third connection 15 of the selected storage device 10a only, but not between the corresponding connections of the unselected storage devices 10b, 10c, 10d. Thereby, sneak currents on the active bit line 16 through unselected storage devices 10b, 10c, 10d which are connected to the active bit line, but not connected to the particular word line are avoided by eliminating a potential difference between the active bit line 16 and the PL lines at the unselected storage devices 10b, 10c, 10d, i.e. there is no net voltage applied between the first and third connections of the unselected storage devices 10b, 10c, 10d.

Avoiding sneak currents on the active bit line is also desirable during write and erase operations in a memory array including resistive memory elements.

For write and erase operations in the storage device 10a including the resistive memory element 11, also bit line 16, word line 17, and PL line 18 are used to apply voltages appropriate for the write and erase operations, respectively.

In the case of MRAMs, a magnetization state of a memory element is changed by a magnetic field the strength of which has to exceed a certain threshold value. The different magnetization states (e.g., two or, in the case of multi level memory cells, multiple states) correspond to respective values stored in the memory element (e.g., “0” and “1” or, in the case of multi level memory cells, multiple bits). Write and erase operations represent changes of the magnetization state of the respective memory element.

In the case of PCRAMs, in order to achieve a change from an amorphous, i.e. a relatively weakly conductive state of the switching active material of a memory element, to a crystalline, i.e. a relatively strongly conductive state of the memory element, an appropriate relatively high heating current pulse has to be applied to the electrodes, the heating current pulse resulting in that the switching active material is heated beyond the crystallization temperature and crystallizes (write operation). Vice versa, a change of state of the switching active material of a memory element from the crystalline, i.e. a relatively strongly conductive state, to the amorphous, i.e. a relatively weakly conductive state, may, for instance, be achieved in that—again by an appropriate (relatively high) heating current pulse—the switching active material is heated beyond the melting temperature and is subsequently “quenched” to an amorphous state by quick cooling (“erase operation”).

In the case of the CBRAMs, the storing of data is performed by use of a switching mechanism based on the statistical bridging of multiple metal rich precipitates in the switching active material of a memory element. Upon application of a write pulse (e.g., positive pulse) to two respective electrodes in contact with the switching active material, the precipitates grow in density until they eventually touch each other, forming a conductive bridge through the switching active material, which results in a high-conductive state of the respective CBRAM memory element. By applying a negative pulse to the respective electrodes, this process can be reversed, hence switching the CBRAM memory element back in its low-conductive state.

Though write and erase operations in PCRAMs and CBRAMs have been described with reference to “two level memory cells” the above explanations are also applicable to multi level memory cells, wherein write and erase operations represent changes between multiple distinct ohmic states.

However, the resistive memory devices (MRAM, PCRAM, and CBRAM) have in common that, for write and erase operations, exact predetermined currents have to be applied to the respective resistive memory element via respective bit lines. Therefore, an accurate control of the current actually applied to the respective memory element is required and, thus, sneak currents on the active bit line are highly undesirable. Hence, the feasibility of avoiding these undesirable sneak currents during write and erase operations provided by embodiments of the invention represents a further advantage of the present invention.

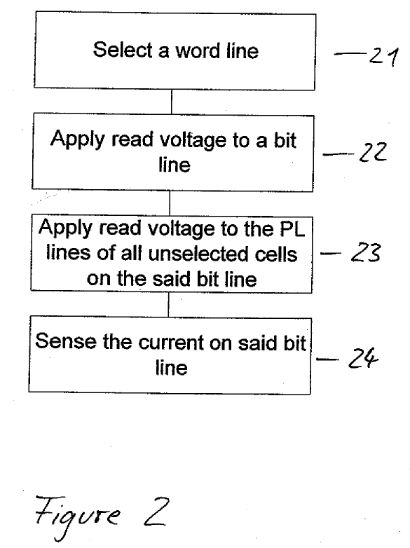

FIG. 2 illustrates a schematic simplified flowchart illustrating a method for reducing sneak current in a memory array in accordance with a further embodiment of the invention.

At 21, illustrated in the flowchart of FIG. 2, with reference to the memory array of FIG. 1, a word line 17 is selected by applying a first voltage to the word line 17, the first voltage being appropriate to set the select devices connected with the selected word line 17 to an “on-state”.

At 22, a second voltage, in the following referred to as read voltage, is applied to the bit line 16 (in the following referred to as active bit line) to which to the storage device 10a to be addressed is connected.

At 23 (which e.g., also might be carried out simultaneously or substantially simultaneously with step 22) the read voltage, i.e. a voltage equal to the second voltage applied to the active bit line in step 22, is applied to the PL lines which are connected to the storage devices 10b, 10c, 10d which are connected to the active bit line, but which are not addressed and selected, respectively, i.e. which are not connected to the selected word line 17 to which a voltage is applied. Thus, a difference in potential is present between the first connection 13 and third connection 15 of the selected storage device 10a only, but not between the corresponding connections of the unselected storage devices 10b, 10c, 10d. Thereby, sneak currents on the active bit line 16 through unselected storage devices 10b, 10c, 10d which are connected to the active bit line, but not connected to the particular word line are avoided by eliminating a potential difference between the active bit line 16 and the PL lines at the unselected storage devices 10b, 10c, 10d, i.e. there is no net voltage applied between the first and third connections of the unselected storage devices 10b, 10c, 10d.

At 24, the current on the active bit line is sensed to read out the value stored in the memory element of the selected storage device. The current on the active bit line can be measured more precisely than in conventional memory arrays including resistive memory elements since undesirable sneak currents on the active bit line through non-selected storage devices are avoided in a memory array including the resistive storage devices described above.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit having a memory array comprising:
a plurality of storage devices arranged as a plurality of rows and a plurality of columns;
where the memory array is configured to reduce sneak currents including receiving a first voltage applied to a particular word line to select a column of storage devices, and a second voltage applied to a particular bit line of the plurality of bit lines to select a row of storage devices, and wherein the second voltage is applied to each of further lines except for a further line being connected to the storage devices of the selected column.

2. The integrated circuit of claim 1, comprising wherein a current on the particular bit line is sensed.

3. The integrated circuit 1, wherein a plurality of further lines comprises a plurality of PL lines.

4. The integrated circuit of claim 1, wherein each storage device of the plurality of storage devices comprises a select device and a resistivity changing memory element.

5. The integrated circuit of claim 4, comprising wherein the select device is a field effect transistor.

6. The integrated circuit 5, comprising wherein a gate of the field effect transistor of each storage device of one column is connected via the second connection of the storage device to one common word line of the plurality of word lines.

7. A memory array comprising:
a plurality of storage devices arranged as a plurality of rows and a plurality of columns;
a plurality of bit lines;
a plurality of word lines;
a plurality of further lines;
wherein the storage devices of one row each have a first connection connected to one common bit line of the plurality of bit lines, and the storage devices of one column each have a second connection connected to one common word line of the plurality of word lines and a third connection connected to one common further line of the plurality of further lines; and
wherein a first voltage is applied to a particular word line to select a column of storage devices being connected with their second connections to the particular word line; a second voltage is applied to a particular bit line of the plurality of bit lines to select a row of storage devices; and
wherein the second voltage is applied to each of the further lines except for a further line being connected to the third connections of the storage devices of the selected column.

8. The memory array of claim 7, comprising wherein a current on the particular bit line is sensed.

9. The memory array of claim 7, wherein the plurality of further lines comprises a plurality of PL lines.

10. The memory array of claim 7, wherein each storage device of the plurality of storage devices comprises a select device and a resistive memory element.

11. The memory array of claim 10, comprising wherein the select device is a field effect transistor.

12. The memory array of claim 11, comprising wherein a gate of the field effect transistor of each storage device of one column is connected via the second connection of the storage device to one common word line of the plurality of word lines.

13. The memory array of claim 10, comprising wherein the resistive memory element is one of the group consisting of Magnetic Random Access Memory, Phase Change Random Access Memory, and Conductive Bridging Random Access Memory.

14. A memory array comprising:
a plurality of storage devices arranged as a plurality of rows and a plurality of columns;
a plurality of bit lines;
a plurality of word lines; and
a plurality of further lines;
wherein the storage devices of one row are each connected to one respective bit line of the plurality of bit lines, and the storage devices of one column are each connected to one respective word line of the plurality of word lines and are also connected to one respective further line of the plurality of further lines; and
wherein a subset of the plurality of storage devices is selected by selecting one or more columns of storage devices by applying a first voltage to one or more word lines connected to the storage devices of the one or more columns, and by applying a second voltage to a particular bit line of the plurality of bit lines, wherein each storage device of the selected subset of storage devices is connected to one of the one or more word lines and the particular bit line; and
wherein the second voltage is applied to each of the further lines which are not connected to one of the storage devices of the selected subset of storage devices.

15. The memory array of claim 14, comprising wherein a current on the particular bit line is sensed.

16. The memory array of claim 14, wherein the plurality of further lines comprises a plurality of PL lines.

17. The memory array of claim 14, wherein each storage device of the plurality of storage devices comprises a first connection, a second connection, and a third connection, wherein the storage devices of one row are connected to one respective bit line of the plurality of bit lines via the first connections, and the storage devices of one column are connected to one respective word line of the plurality of word lines via the second connections and are also connected to a respective one of the plurality of further lines via the third connections.

18. The memory array of claim 17, wherein each storage device of the plurality of storage devices further comprises a select device and a resistive memory element.

19. The memory array of claim 18, comprising wherein the select device is a field effect transistor.

20. The memory array of claim 19, comprising wherein a gate of the field effect transistor of each storage device of one column is connected via the second connection of the respective storage device to one common word line of the plurality of word lines.

21. The memory array of claim 18, comprising wherein the resistive memory element is one of the group consisting of Magnetic Random Access Memory, Phase Change Random Access Memory, and Conductive Bridging Random Access Memory.

22. An integrated circuit device comprising a memory array according to claim 10.

23. An electronic system comprising an integrated circuit device according to claim 22.

24. A method for reducing sneak current in a memory array, comprising:
a plurality of storage devices arranged as a plurality of rows and a plurality of columns;
a plurality of bit lines;
a plurality of word lines; and
a plurality of further lines;
wherein the storage devices of one row are each connected to one common bit line of the plurality of bit lines, and the storage devices of one column are each connected to one common word line of the plurality of word lines and are also connected to one common further line of the plurality of further lines;
the method comprising:
selecting a particular column of storage devices by applying a first voltage to the word line connected to the storage devices of the particular column;
applying a second voltage to a bit line of the plurality of bit lines; and
applying the second voltage to each of the further lines except for a further line being connected to the storage devices of the particular selected column.

25. The method of claim 24, comprising wherein a current on the bit line to which the second voltage is applied is sensed.

26. The method of claim 25, comprising wherein the current on the bit line to which the second voltage is applied is sensed to read a value stored in a storage device connected to both the bit line to which the second voltage is applied and the word line to which the first voltage is applied.

27. The method of claim 24, comprising wherein the second voltage is applied to the bit line to carry out a write operation in a storage device connected to both the particular bit line to which the second voltage is applied and the word line to which the first voltage is applied.

28. The method of claim 24, wherein the plurality of further lines comprises a plurality of PL lines.

29. The method of claim 24, wherein each storage device of the plurality of storage devices comprises a select device and a resistive memory element.

30. The method of claim 29, comprising wherein the select device is a field effect transistor.

31. The method of claim 30, comprising wherein a gate of the field effect transistor of each storage device of one column is connected via the second connection of the storage device to one common word line of the plurality of word lines.

32. The method of claim 29, comprising wherein the resistive memory element is one of the group consisting of Magnetic Random Access Memory, Phase Change Random Access Memory, and Conductive Bridging Random Access Memory.
